(19) United States
(12) Patent Application Publication
(10) Pub. No.: US 2026/0101601 A1
(43) Pub. Date: Apr. 9, 2026

(54) PIXEL SENSOR AND METHODS FOR MANUFACTURING PIXEL SENSOR AND DEEP TRENCH ISOLATION STRUCTURE THEREOF

(71) Applicant: Taiwan Semiconductor Manufacturing Company, Ltd., Hsinchu (TW)

(72) Inventors: Yi-Hsuan FAN, Hsinchu (TW); Wen-Sheng WANG, Hsinchu (TW)

(73) Assignee: Taiwan Semiconductor Manufacturing Company, Ltd., Hsinchu (TW)

(21) Appl. No.: 18/910,231

(22) Filed: Oct. 9, 2024

(51) Int. Cl. H01L 27/146

(52) U.S. Cl. CPC H10F 39/807; H10F 39/014; H10F 39/18

(57) ABSTRACT

A pixel sensor including a substrate, a bottom insulating layer, an epitaxial layer, a photodiode and a deep trench isolation (DTI) structure is provided. The bottom insulating layer is disposed on the substrate. The epitaxial layer is disposed on the bottom insulating layer, and the bottom insulating layer isolates the substrate and the epitaxial layer. The photodiode is located in the epitaxial layer, and the photodiode includes an n-type doped extension region. The depth of the n-type doped extension region is at least greater than 4 microns. The deep trench isolation structure is located in the epitaxial layer, the deep trench isolation structure is adjacent to the photodiode, and the depth of the deep trench isolation structure is at least greater than 4 microns.

### BACKGROUND

A complementary metal oxide semiconductor (CMOS) image sensor may include a plurality of pixel sensors. A pixel sensor of the CMOS image sensor may include a transfer transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1C illustrate cross-sectional schematic diagrams of a pixel sensor along the cross-section A-A of the pixel array in FIG. 9 according to an embodiment.

FIGS. 2A to 2C illustrate cross-sectional schematic diagrams of a pixel sensor according to another embodiment.

FIGS. 3A to 3C illustrate cross-sectional schematic diagrams of a pixel sensor according to another embodiment.

FIGS. 4A to 4C illustrate cross-sectional schematic diagrams of a pixel sensor according to another embodiment.

FIGS. 5A to 5C illustrate cross-sectional schematic diagrams of a DTI structure according to an embodiment.

FIGS. 6A to 6F illustrate a schematic diagram of a method of manufacturing a DTI structure according to an embodiment.

FIGS. 7A to 7C illustrate schematic diagrams of forming an epitaxial layer on a bottom insulating layer according to an embodiment.

FIGS. 8A to 8E illustrate schematic diagrams of a method of manufacturing a pixel sensor according to an embodiment.

FIG. 9 illustrates a top view of a pixel array.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

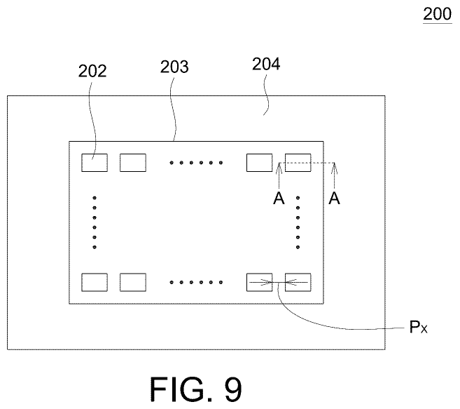

FIG. 9 illustrates a top view of a pixel array 200. In some embodiments, the pixel array 200 may be included in an image sensor. The image sensor may include a complementary metal oxide semiconductor (CMOS) image sensor, a backside illuminated (BSI) CMOS image sensor, a front side illuminated (FSI) CMOS image sensor, or another type of image sensor. As shown in FIG. 9, the pixel array 200 may include a plurality of pixel sensors 202. The pixel sensors 202 may be arranged in a grid or array. In some embodiments, the pixel sensor 202 is square or other shapes, such as rectangle, circle, octagon, and diamond, etc.

The pixel sensors 202 may be configured to sense and/or accumulate incident light (e.g., light directed to pixel array 200). For example, the pixel sensors 202 may absorb and accumulate photons of incident light in a photodiode. The accumulation of photons in a photodiode can produce charges that are representative of the intensity or brightness of the incident light (e.g., a larger amount of charges can correspond to greater intensity or brightness, while a smaller amount of charges can correspond to lower intensity or brightness).

In some embodiments, the size (e.g., width or diameter) of the pixel sensor 202 is about 1 micron (μm). In some embodiments, the size (e.g., width or diameter) of the pixel sensor 202 is less than about 1 micron. In these examples, the pixel sensors 202 may be referred to as a sub-micron pixel sensor. The sub-micron pixel sensors can reduce the pitch Px of the pixel sensors in the pixel array 200 (e.g., the distance between adjacent pixel sensors, is about 0.05 microns), which can increase the density of the pixel sensors 202 in pixel array 200 (this can improve the performance of pixel array 200). As shown above, the CMOS image sensor may include a pixel array 200 and a logic unit 204 surrounding the pixel array 200.

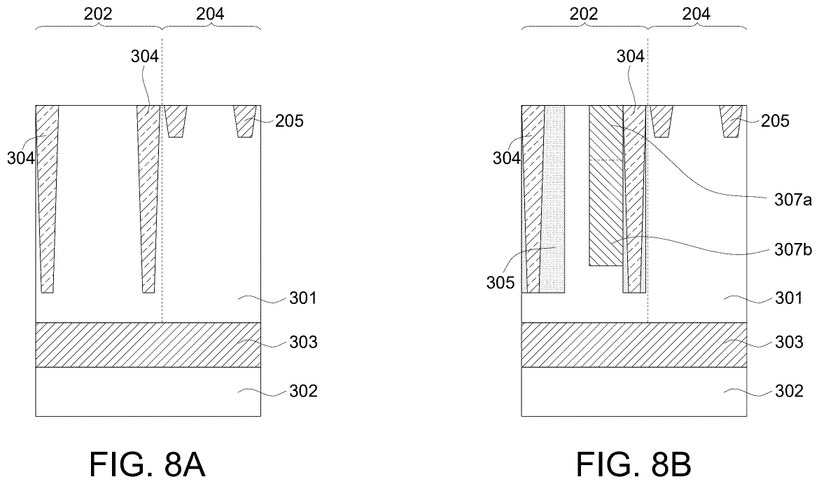

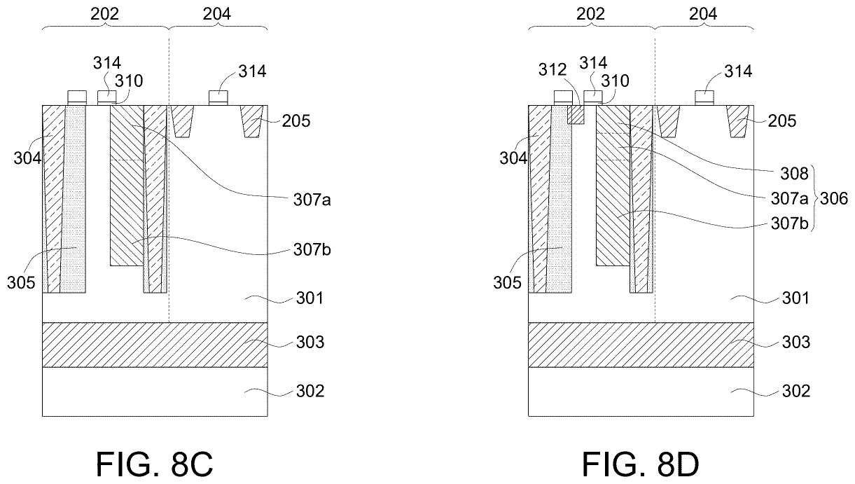

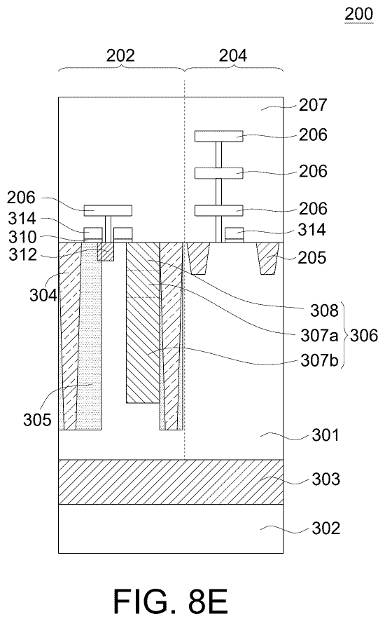

In addition, the pixel array 200 may be electrically connected to the back-end-of-line (BEOL) metallization stack of the CMOS image sensor (see FIG. 8E). The BEOL metallization stack can electrically connect the pixel array 200 to the control circuitry, which can be used to measure the incident light accumulated in the pixel sensor 202 and convert the measurement results into electrical signals. For front-illuminated (FSI) CMOS image sensors, the BEOL metallization stack can be located between the transistor layer and the lens layer (not shown).

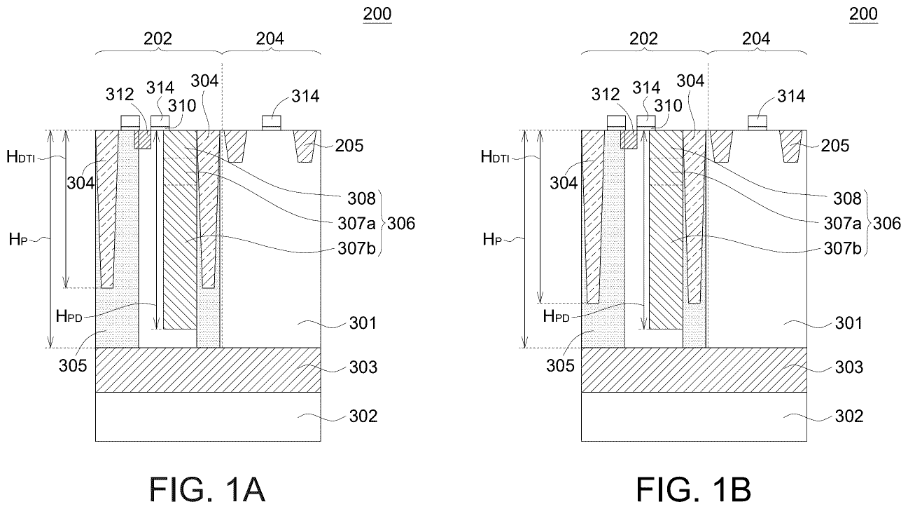

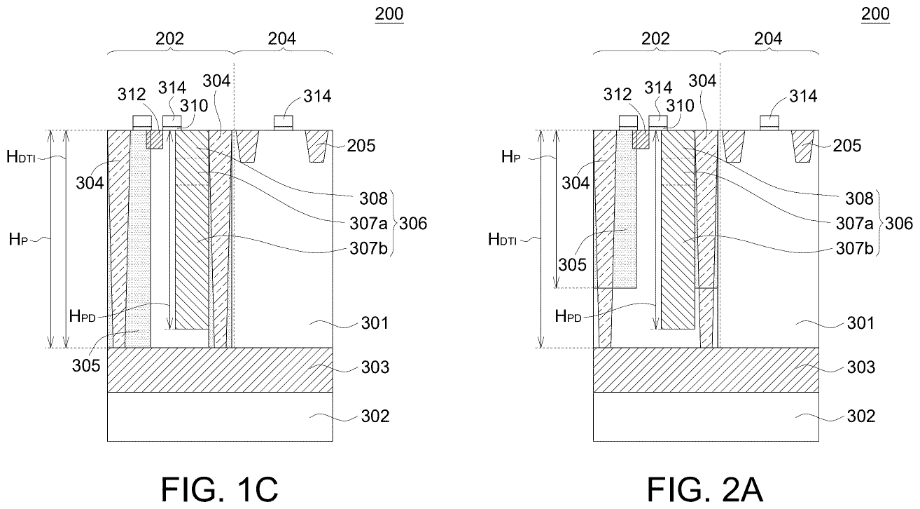

Reference cross-section A-A is used in the drawings set forth herein (e.g., FIGS. 1A-1C, FIGS. 2A-2C, FIGS. 3A-3C, FIGS. 4A-4C). The cross-section A-A lies in the plane across the pixel sensor 202 and the logic unit 204 of the pixel array 200. For clarity, subsequent figures refer to this reference cross-section. In some drawings, to facilitate the illustration of the drawings, some reference numbers of components or features shown therein may be omitted to avoid obscuring other components or features.

FIGS. 1A to 1C illustrate cross-sectional schematic diagrams of a pixel sensor 202 along the cross-section A-A of the pixel array 200 in FIG. 9 according to an embodiment. The pixel sensor 202 may include a substrate 302, a bottom insulating layer 303, and an epitaxial layer 301. The substrate 302 may include a semiconductor die substrate, a semiconductor wafer, or a stacked semiconductor wafer. In some embodiments, the substrate 302 is formed from the following materials: silicon (Si), silicon-containing materials (e.g., silicon germanium), III-V compound semiconductor materials (e.g., gallium arsenide (GaAs)), silicon-on-insulator (SOI) or another type of semiconductor material capable of generating charges from photons of incident light. In some embodiments, the substrate 302 is formed with a first type doped material (e.g., a p-doped material or an n-doped material), such as p-doped silicon. The compound semiconductor materials may include silicon carbide, gallium arsenic, gallium phosphide, indium phosphide, indium arsenide, and indium antimonide or combination thereof. The epitaxy layer 301 is formed by a process in which semiconductor crystals are grown onto existing semiconductor materials. The epitaxial layer 301 is generally obtained by using gas precursors.

The pixel sensor 202 may include a photodiode 306 included in the epitaxial layer 301. The photodiode 306 may include multiple regions doped with various types of ions to form a p-n junction or PIN junction (e.g., an interface between a p-type portion, an intrinsic (or undoped) type portion, and an n-type portion). For example, the substrate 302 may be doped with n-type dopants to form one or more n-type regions 307a and one or more n-type doped extension regions 307b of the photodiode 306, and the epitaxial layer 301 may be doped with p type dopants to form p-type region 308 of the photodiode 306. The photodiode 306 may be configured to absorb photons of incident light. Due to the photoelectric effect, the absorption of photons causes the photodiode 306 to accumulate charges (called photocurrent). Photons may bombard the photodiode 306 and cause electrons emitting from the photodiode 306.

Referring to FIG. 1A, the pixel sensor 202 can be electrically isolated and optically isolated by a deep trench isolation (DTI) structure 304 included in the pixel array 200. The DTI structure 304 may include a plurality of interconnected trenches filled with dielectric material (e.g., oxide). The trench of the DTI structure 304 may be located at a peripheral boundary of the pixel sensor 202 such that the DTI structure 304 surrounds the pixel sensor 202 (including the photodiode 306 and the drain region 312), as shown in FIG. 1A. In addition, the trench of the DTI structure 304 can extend into the epitaxial layer 301 in which the pixel sensor 202 is formed, so as to surround the photodiode 306 and other structures of the pixel sensor 202 in the epitaxial layer 301. In these embodiments, the DTI structure 304 may include an isolation structure with a high aspect ratio formed from the front side of pixel array 200.

The regions included in the photodiode 306 may be stacked and/or arranged in a first direction (i.e., a vertical direction from the top of the photodiode 306 to the substrate 302). For example, a first type (p-type) region 308 may be located over the one or more second type (n-type) regions 307a. The p-type region 308 may provide noise isolation for the one or more n-type regions 307a and may facilitate the generation of photocurrent in the photodiode 306. In some embodiments, p-type region 308 is located on the top surface of the epitaxial layer 301 (e.g., downward from the top surface of substrate 302), and n-type doped extension region 307b is spaced apart from the bottom surface of epitaxial layer 301 (e.g., separated by at least 0.2 microns) to form a p-n junction between the n-type doped extension region 307b and the epitaxial layer 301. The bottom insulating layer 303 is used to isolate between the epitaxial layer 301 and the substrate 302, which can reduce the dark current or cross-talk leakage of the pixel sensor 202 from flowing out through the substrate 302.

The n-type region 307a may be located above the n-type doped extension region 307b. The n-type doped extension region 307b may be referred to as a deep n-type region or a deep n-well, and the n-type region 307a of the photodiode 306 may be extended downwardly. This may provide increased area for photon absorption in the photodiode 306. In addition, the one or more n-type regions 307a and n-type doped extension regions 307b may have different doping concentrations. For example, n-type region 307a has a greater n-type dopant concentration relative to n-type doped extension region 307b. As a result, an n-type dopant gradient is formed, which may increase electron upward migration in the photodiode 306.

In addition, the pixel sensor 202 may include a drain region 312, and the drain region 312 may include a highly doped n-type region (e.g., an n⁺ doped region). In addition, the pixel sensor 202 may include a transfer gate 314 to control the transfer of photocurrent between the photodiode 306 and the drain region 312. The transfer gate 314 may be energized (e.g., by applying a voltage or current to transfer gate 314) to form a conductive path between the photodiode 306 and the drain region 312. The conductive channel can be removed or closed by de-energizing the transfer gate 314, which blocks and/or prevents photocurrent from flowing between the photodiode 306 and the drain region 312.

The pixel sensor 202 may include a deep p-well (DPW) 305 adjacent to and at least partially surrounding the photodiode 306. In the epitaxial layer 301, the deep p-well region 305 may include a circular or annular shape in a top view of pixel sensor 202. The deep p-well region 305 may include p-type doped silicon material. In some embodiments, the DTI structure 304 may be located in deep p-well region 305. The DTI structure 304 may include one or more trenches extending down into the epitaxial layer 301 and adjacent to the photodiode 306 and the drain region 312.

In a top view of the pixel sensor 202, the DTI structure 304 may surround the photodiode 306 and the drain region 312. In other words, the photodiode 306, the transfer gate 314 and the drain region 312 may be located within the perimeter of the DTI structure 304 of the pixel sensor 202. The DTI structure 304 may provide an optical isolation between the pixel sensor 202 and one or more adjacent pixel sensors to reduce the amount of optical crosstalk between the pixel sensor 202 and adjacent pixel sensors. Specifically, the DTI structure 304 can absorb, refract and/or reflect the photons of the incident light, which can reduce the amount of the incident light from entering into adjacent pixel sensors through the pixel sensor 202 and being sensed by the adjacent pixel sensor.

Additionally, a gate dielectric layer 310 may be formed over the front side surface of the epitaxial layer 301. The gate dielectric layer 310 may include a dielectric material such as tetraethyl orthosilicate (TEOS) or another type of dielectric material.

In order to reduce the dark current or cross-talk leakage of the pixel sensor 202 flowing into adjacent pixel sensors through the photodiode 306, the depth of the DTI structure 304 can be changed to enhance noise isolation and/or light leakage isolation. Referring to FIGS. 1A to 1C, the depth H_{DTI} of the DTI structure 304 is at least greater than 4 microns and less than or equal to about 20 microns or higher. In FIGS. 1A and 1B, the depth H_{DTI} of the DTI structure 304 is smaller than the depth H_{P} of the deep p-well region 305. In FIG. 1C, the depth H_{DTI} of the DTI structure 304 is substantially equal to the depth H_{P} of the deep p-well region 305. The deeper the DTI structure 304 is, the better the noise isolation and/or light leakage isolation performance of the pixel sensor 202 is. In some embodiments, The DTI structure 304 is in contact with the bottom surface of the epitaxial layer 301 or spaced apart from the bottom surface of epitaxial layer 301 (e.g., separated by up to 1 micron). Additionally, the width of the top surface of DTI structure 304 may be greater than the width of the bottom surface thereof.

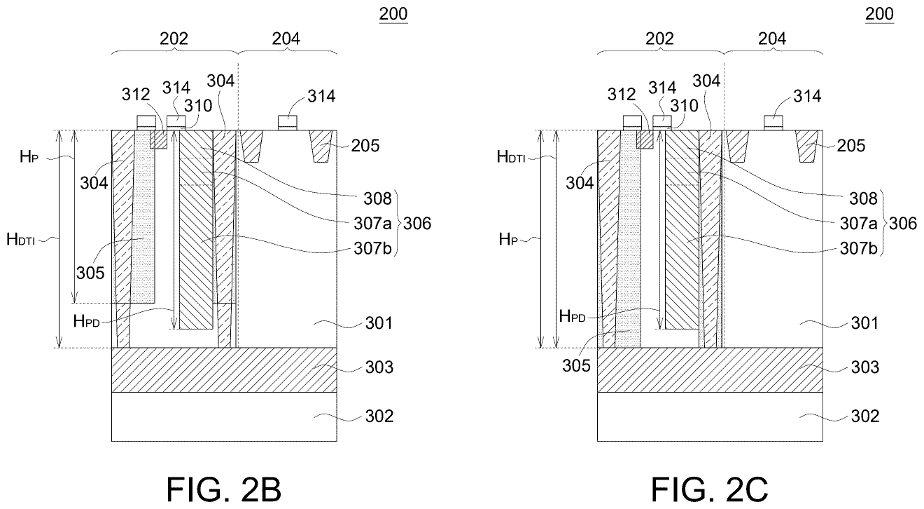

Referring to FIGS. 2A to 2C, the depth H_{DTI} of the DTI structure 304 is substantially equal to the depth of the epitaxial layer 301, and the depth H_{P} of the deep p-well region 305 is at least greater than 4 microns, less than or equal to about 20 microns or higher. In FIGS. 2A and 2B, the depth H_{DTI} of the DTI structure 304 is greater than the depth H_{P} of the deep p-well region 305. In FIG. 2C, the depth H_{DTI} of the DTI structure 304 is substantially equal to the depth H_{P} of the deep p-well region 305. The deeper the deep p-well region 305 is, the better the noise isolation and/or light leakage isolation performance of the pixel sensor 202 is.

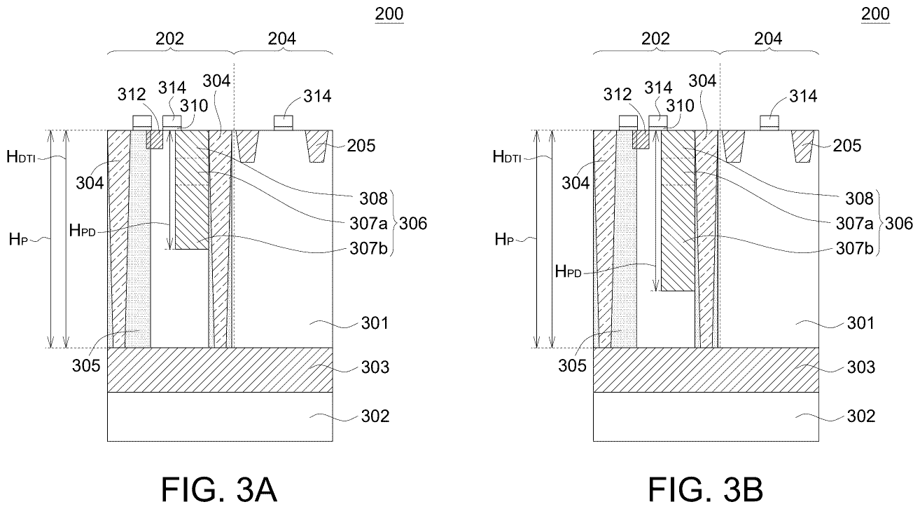

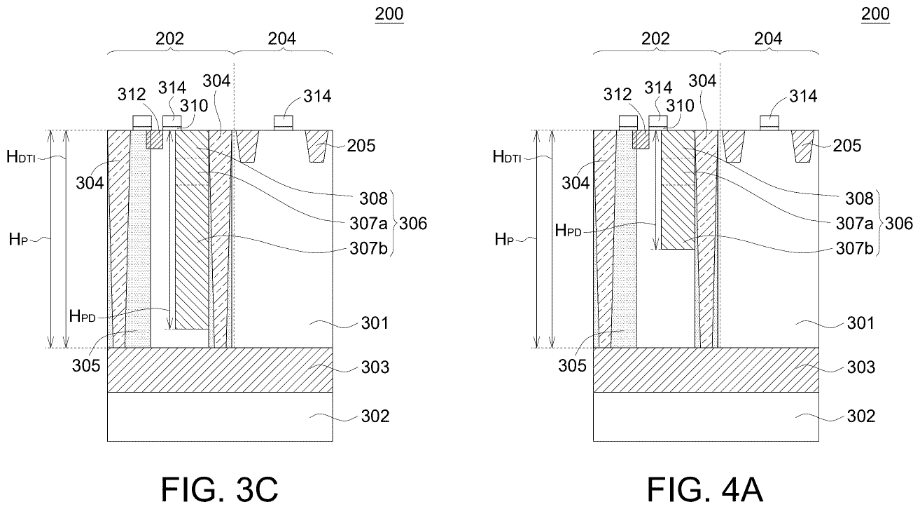

Referring to FIGS. 3A to 3C, the depth H_{DTI} of the DTI structure 304 and the depth H_{P} of the deep p-well region 305 are substantially equal to the depth of the epitaxial layer 301. The total depth H_{PD} of the p-type region 308, the n-type region 307a and the n-type doped extension region 307b is at least greater than 4 microns and less than or equal to about 20 microns or greater. In FIGS. 3A to 3C, the total depth H_{PD} of the p-type region 308, the n-type region 307a and the n-type doped extension region 307b is smaller than the depth H_{DTI} of the DTI structure 304 or the depth H_{P} of the deep p-well region 305. Since the total depth H_{PD} of the p-type region 308, the n-type region 307a, and the n-type doped extension region 307b is increased, the photodiode 306 can be configured to absorb more photons of non-visible light (such as infrared rays), thereby improving the photoelectric conversion efficiency of the photodiode 306 to non-visible light.

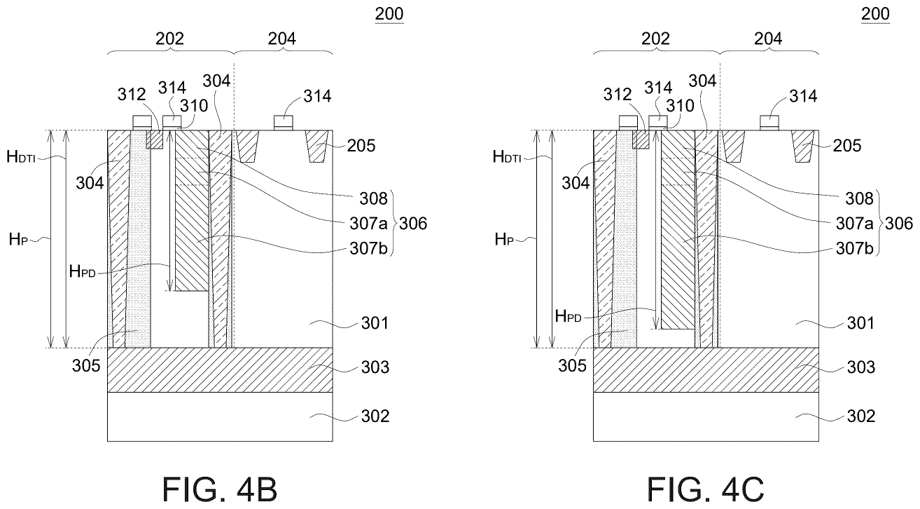

Referring to FIGS. 4A to 4C, the depth H_{DTI} of the DTI structure 304, the depth H_{P} of the deep p-well region 305, and the total depth H_{PD} of the p-type region 308, the n-type region 307a and the n-type doped extension region 307b are configured substantially as shown in FIG. 3A to 3C, the difference lies in the doping concentration of the p-type dopant in the epitaxial layer 301. In some embodiments, the doping concentration of the p-type dopant is less than 1E16 atoms/cm³ and is less than the doping concentration of the p-type dopant in the substrate 302. In FIGS. 4A to 4C, the doping concentration of the p-type dopant in the epitaxial layer 301 can be reduced from 1E14 atoms/cm³ to 1E11 atoms/cm³ or lower. The lower the doping concentration of the p-type dopant in the epitaxial layer 301, the easier it is for the n-type doped extension region 307b to diffuse downward from the epitaxial layer 301 toward the substrate 302 and have a deeper depth, so that it is more helpful for the photoelectric conversion efficiency of the photodiode 306 to non-visible light.

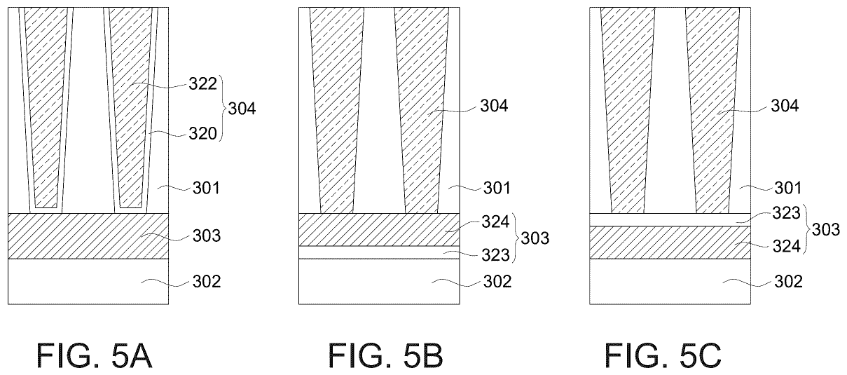

Referring to FIG. 5A, the DTI structure 304 may include a liner layer or a high dielectric constant (high-k) layer 320 between the epitaxial layer 301 of the pixel sensor 202 and the oxide layer 322 of the DTI structure 304 to further improve the reflectivity of the DTI structure 304. The oxide layer 322 can serve to reflect incident light toward the photodiode 306 to increase the quantum efficiency of the pixel sensor 202 and reduce the optical crosstalk between the pixel sensor 202 and one or more adjacent pixel sensors. In some embodiments, the oxide layer 322 includes an oxide material (e.g., silicon oxide (SiOx)). In some embodiments, silicon nitride (SiNx), silicon carbide (SiCx), or mixtures thereof (e.g., silicon carbonitride (SiCN), silicon oxynitride (SiON)) or another type of dielectric material is used instead of the oxide layer 322. In some embodiments, the liner layer or high-k layer 320 may include, for example, hafnium oxide (HfO₂), aluminum trioxide (Al₂O₃), and/or tantalum oxide (Ta₂O₅). The thickness of the liner layer or high-k layer 320 may be between 10 Å and 120 Å.

Referring to FIGS. 5B and 5C, the bottom insulating layer 303 may include an oxide layer 324 and a high-k layer 323 located on the substrate 302 to further improve the reflectivity of the bottom insulating layer 303. The oxide layer 324 may be located above the high-k layer 323, or the oxide layer 324 may be located under the high-k layer 323. The oxide layer 324 includes an oxide material such as silicon oxide (SiOx). In some embodiments, silicon nitride (SiNx), silicon carbide (SiCx), or mixtures thereof (e.g., silicon carbonitride (SiCN), silicon oxynitride (SiON)) or another type of dielectric material is used instead of oxide layer 324. The high-k layer 323, having a k value higher than 3.9, may include, for example, hafnium oxide (HfO₂), aluminum trioxide (Al₂O₃), and/or tantalum oxide (Ta₂O₅). The bottom insulating layer 303 may be formed using chemical vapor deposition (CVD), physical vapor deposition (PVD), atomic layer deposition (ALD), or another type of deposition technology. The thickness of the oxide layer 324 may be greater than or equal to 2 microns, and the thickness of the high dielectric constant layer 323 may be between 10 Å and 120 Å.

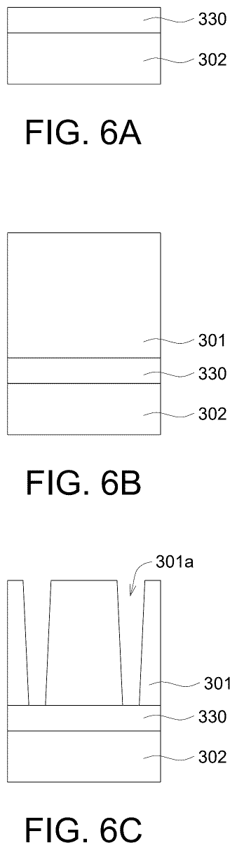

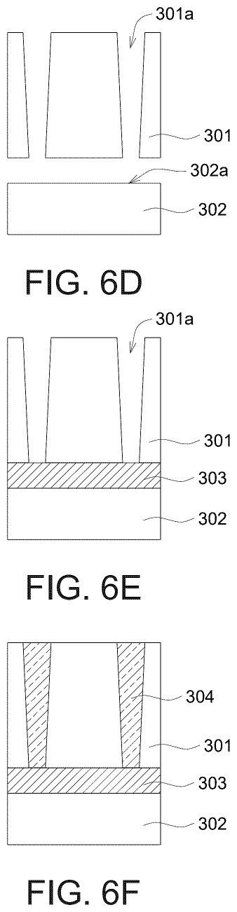

Referring to FIGS. 6A to 6F, schematic diagrams of a method of manufacturing the DTI structure 304 according to an embodiment are illustrated. First, a seed layer 330 is formed on the substrate 302. The seed layer 330 is, for example, silicon germanium or other semiconductor materials. An epitaxial layer 301 is formed on the seed layer 330. The depth of the epitaxial layer 301 is greater than 4 microns and less than or equal to 20 microns. The depth of the epitaxial layer 301 determines the depth of the photodiode subsequently formed in the epitaxial layer 301. In FIG. 6C, the epitaxial layer 301 is etched to form one or more trenches 301a. From a top view, the trenches 301a may be annular or other shapes. Next, the seed layer 330 exposed in the trench 301a is etched to remove the seed layer 330. Next, a thermal oxidation or deposition process is performed on the substrate surface area 302a below the epitaxial layer 301 to form a bottom insulating layer 303 between the epitaxial layer 301 and the substrate 302. The bottom insulating layer 303 is, for example, an oxide layer 324 or a plurality of dielectric layers including an oxide layer 324 and a high-k layer 323. In FIG. 6F, the oxide layer 320 or a plurality of dielectric layers including the oxide layer 320 and the high-k layer 322 is filled in the trench 301a to form the DTI structure 304. The high-k layer 322 is located between the oxide layer 320 and the epitaxial layer 301.

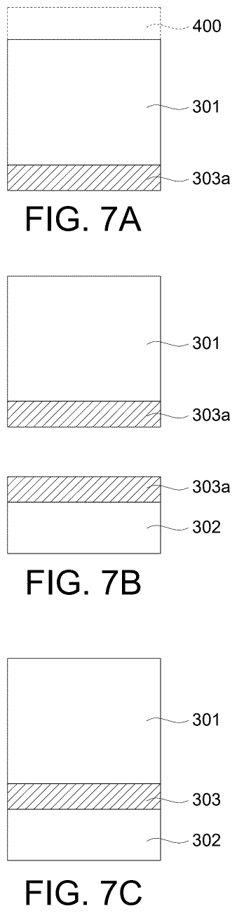

Referring to FIGS. 7A to 7C, schematic diagrams of forming an epitaxial layer 301 on the bottom insulating layer 303 according to an embodiment are illustrated. In FIG. 7A, an epitaxial layer 301 is formed on the semiconductor substrate 400 (such as a p-type substrate) through a deposition process, and an insulating material 303a is formed on the epitaxial layer 301 through another deposition process. The semiconductor substrate 400 is polished and removed (shown as a dotted line in the figure), leaving only the insulating material 303a on the epitaxial layer 301, and the insulating material 303a can serve as the subsequent bottom insulating layer 303. In FIG. 7B, a substrate 302 is provided, and another insulating material 303a is formed on the substrate 302 through deposition process. In FIG. 7B, the insulating material 303a can be the same as the insulating material 303a in FIG. 7A and forms the bottom insulating layer 303 through bonding process. In FIG. 7C, after bonding process, the bottom insulating layer 303 is disposed between the substrate 302 and the epitaxial layer 301. The epitaxial layer 301 and the bottom insulating layer 303 may be formed using CVD, PVD, ALD or another type of deposition technology.

Referring to FIGS. 8A to 8E, schematic diagrams of a method of manufacturing a pixel sensor 202 according to an embodiment are illustrated. In FIG. 8A, a DTI structure 304 is formed in the epitaxial layer 301 of the pixel unit 203. The depth of the DTI structure 304 is at least greater than 4 microns. The shallow trench isolation (STI) structure 205 located in the epitaxial layer 301 of the logic unit 204 is a conventional component and will not be described in detail here. The depth of the STI structure 205 is much smaller than the depth of the DTI structure 304. In FIG. 8B, a deep p-well region 305 is formed in the epitaxial layer 301, and a DTI structure 304 may be located in the deep p-well region 305. The deep p-well region 305 may include p-type doped silicon material, and the concentration of the p-type dopants is less than 1E16 atoms/cm³, for example, between 1E14 and 1E12 atoms/cm³. In FIG. 8B, n-type region 307a and n-type doped extension region 307b are formed within the perimeter surrounded by the deep p-well region 305. The n-type doped extension region 307b is spaced apart from the bottom surface of the epitaxial layer 301, so that a p-n junction is formed between the n-type doped extension region 307b and the epitaxial layer 301. The n-type region 307a and the n-type doped extension region 307b include n-type dopants, and the concentration of the n-type dopants is less than 1E16 atoms/cm³, for example, between 1E14 and 1E12 atoms/cm3, and the doping concentration of the n-type doped extension region 307b may be lower than the doping concentration of the n-type region 307a. In FIG. 8C, a transfer gate 314 is formed on the top surface of the epitaxial layer 301. In FIG. 8D, a drain region 312 and a p-type region 308 are formed in the epitaxial layer 301. The drain region 312 may include a highly doped n-type region (for example, an n⁺ doped region), and the p-type region 308 may include a highly doped p-type region. The doping concentration of the p-type region 308 is less than 1E16 atoms/cm³, for example, between 1E14 and 1E12 atoms/cm³. The transfer gate 314 is located between the drain region 312 and the p-type region 308 to control the transfer of photocurrent between the photodiode 306 and the drain region 312. In FIG. 8E, a metallization stack (including one or more metallization layers 206) and an inter-metal dielectric layer 207 (IMD) are formed on the epitaxial layer 301, and the photocurrent between the photodiode 306 and the drain region 312 can be transmitted to the control circuitry through the metallization stack.

The inter-metal dielectric layer 207 may include an oxide material (e.g., silicon oxide (SiOx) or another type of dielectric material. The metallization layer 206 may include one or more conductive materials (e.g., tungsten (W), cobalt (Co), ruthenium (Ru), copper (Cu), and/or another type of conductive material). The inter-metal dielectric layer 207 may be formed using CVD, PVD, ALD or another type of deposition technology.

In some embodiments, a color filter layer (not shown) is included above the inter-metal dielectric layer 207. The color filter layer includes a visible light color filter configured to filter visible light of a specific wavelength or range of wavelengths (e.g., red light, blue light, or green light). In some embodiments, the color filter layer includes a near infrared (NIR) filter (e.g., a NIR bandpass filter) configured to allow wavelengths associated with NIR light to pass the color filter layer and blocks other wavelengths of light. In addition, the color filter patterns are Bayer or mosaics patterns, such as red, green, blue and IR additive color filters (e.g., RGB, RGBG, GRGB, RGIRG or BGIRG), cyan, magenta, yellow and base (black) subtractive color filter (e.g., CMYK) patterns, a combination of the two, or others.

The wavelength of infrared (IR) light is typically in the range of 750 nm to about 950 nm, and the typical absorption depth of a silicon substrate for an IR light wavelength of 950 nm is about 10 μm. Therefore, in order to improve the quantum efficiency or photosensitivity of the photodiode 306 to infrared (IR) light, a thicker epitaxial layer 301 with a deeper implanted photodiode 306 is needed to increase the absorption of IR light, and at the same time, this would require a deeper isolation DTI structure 304. Compared with traditional photolithography and implantation processes, the implantation depth of the photodiode is limited to about 2 μm to 3 μm. The implantation depth of the photodiode 304 of this embodiment can be greater than 4 μm, which is sufficient to completely absorb IR light, thereby improving the performance of the image sensor 200. In addition, the maximum aspect ratio (depth to width ratio) of the DTI structure 304 can also be relatively increased, which will further increase the depth of the DTI structure 304.

The present disclosure relates to a pixel sensor and methods for manufacturing the pixel sensor and a deep trench isolation structure thereof. The pixel sensor includes a photodiode and a deep trench isolation (DTI) structure in the epitaxial layer. The implantation depth of the photodiode is at least greater than 4 microns so that the quantum efficiency of the pixel sensor of CMOS image sensor can be improved. In addition, the depth of the DTI structure is at least greater than 4 microns so that the noise isolation and/or light leakage isolation performance of the pixel sensor of CMOS image sensor can be improved.

According to some embodiments of the present disclosure, a pixel sensor including a substrate, a bottom insulating layer, an epitaxial layer, a photodiode and a deep trench isolation (DTI) structure is provided. The bottom insulating layer is disposed on the substrate. The epitaxial layer is disposed on the bottom insulating layer, and the bottom insulating layer isolates the substrate and the epitaxial layer. The photodiode is located in the epitaxial layer, and the photodiode includes an n-type doped extension region. The photodiode and the n-type doped extension region have a first depth. The deep trench isolation structure is located in the epitaxial layer, the deep trench isolation structure is adjacent to the photodiode, and a second depth of the deep trench isolation structure is at least greater than the first depth.

According to some embodiments of the present disclosure, a method for manufacturing a deep trench isolation (DTI) structure is provided, including the following steps. A seed layer is formed on a substrate. An epitaxial layer is formed on the seed layer, and the depth of the epitaxial layer is greater than 4 microns. The epitaxial layer is etched to form one or more trenches. The seed layer exposed in the trench is etched to remove the seed layer. A deposition process is performed on a substrate surface area below the epitaxial layer to form a bottom insulating layer between the epitaxial layer and the substrate. An oxide layer is filled in the trench, and the oxide layer forms a deep trench isolation structure in the epitaxial layer.

According to some embodiments of the present disclosure, a method for manufacturing a pixel sensor is provided, including the following steps. A bottom insulating layer is formed on the substrate. An epitaxial layer is disposed on the bottom insulating layer, and the bottom insulating layer isolates the substrate and the epitaxial layer. A deep trench isolation structure is formed in the epitaxial layer, and the depth of the deep trench isolation structure is at least greater than 4 microns. A photodiode is formed in the epitaxial layer, the deep trench isolation structure is adjacent to the photodiode, the photodiode includes an n-type doped extension region, and the depth of the photodiode and the n-type doped extension region is at least greater than 4 microns.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel sensor, comprising:
a first type doped substrate:
a bottom insulating layer disposed on the substrate;
an epitaxial layer disposed on the bottom insulating layer, and the bottom insulating layer isolating the substrate and the epitaxial layer;
a photodiode located in the epitaxial layer, the photodiode including an second type doped extension region extending along a first direction from the photodiode toward the first type doped substrate, wherein the photodiode and the second type doped extension region have a first depth; and
a deep trench isolation structure located in the epitaxial layer, the deep trench isolation structure being adjacent to the photodiode, and a second depth of the deep trench isolation structure being greater than the first depth.

2. The pixel sensor of claim 1, wherein the second type doped extension region is spaced apart from a bottom surface of the epitaxial layer by a distance.

3. The pixel sensor of claim 2, wherein a p-n junction is formed between the second type doped extension region and the epitaxial layer.

4. The pixel sensor of claim 1, wherein the photodiode comprises a first type region and a second type region, the first type region, the second type region and the second type doped extension region are connected and arranged in a vertical direction of the epitaxial layer.

5. The pixel sensor of claim 1, wherein the deep trench isolation structure is in contact with or separated by a distance from a bottom surface of the epitaxial layer.

6. The pixel sensor of claim 1, further comprising a deep p-well region, the deep trench isolation structure being located in the deep p-well region, and a depth of the deep p-well region is at least greater than 4 microns.

7. The pixel sensor of claim 1, wherein the bottom insulating layer comprises an oxide layer and a high dielectric constant layer located on the substrate.

8. A method for manufacturing a deep trench isolation structure, comprising:
forming a seed layer on a substrate;
forming an epitaxial layer on the seed layer, a depth of the epitaxial layer being greater than 4 microns;
etching the epitaxial layer to form one or more trenches;
etching the seed layer exposed in the trench to remove the seed layer;
performing a deposition process on a substrate surface area below the epitaxial layer to form a bottom insulating layer between the epitaxial layer and the substrate; and
filling an oxide layer in the trench, and the oxide layer forms a deep trench isolation structure in the epitaxial layer.

9. The method of claim 8, further comprising filling a high dielectric constant layer in the trench, the high dielectric constant layer being located between the oxide layer and the epitaxial layer.

10. The method of claim 8, wherein the bottom insulating layer is an oxide layer or a plurality of dielectric layers including the oxide layer and a high dielectric constant layer.

11. A method for manufacturing a pixel sensor, comprising:
forming a bottom insulating layer on a first type doped substrate;
disposing an epitaxial layer on the bottom insulating layer, and the bottom insulating layer isolating the first type doped substrate and the epitaxial layer;
forming a deep trench isolation structure in the epitaxial layer, a depth of the deep trench isolation structure being at least greater than 4 microns; and
forming a photodiode in the epitaxial layer, the deep trench isolation structure being adjacent to the photodiode, the photodiode including a second type doped extension region, and a depth of the photodiode and the second type doped extension region being at least greater than 4 microns.

12. The method of claim 11, further comprising forming a deep p-well region in the epitaxial layer, the deep trench isolation structure being located in the deep p-well region, and a depth of the deep p-well region being at least greater than 4 microns.

13. The method of claim 11, wherein the n-type doped extension region is spaced apart from a bottom surface of the epitaxial layer by a distance.

14. The method of claim 13, wherein a p-n junction is formed between the n-type doped extension region and the epitaxial layer.

15. The method of claim 11, wherein forming the photodiode further includes forming a first type region and a second type region in the epitaxial layer, the first type region, the second type region and the second type doped extension regions being connected and arranged in a vertical direction of the epitaxial layer.

16. The method of claim 11, wherein the deep trench isolation structure is in contact with or separated by a distance from a bottom surface of the epitaxial layer.

17. The method of claim 11, wherein the bottom insulating layer includes an oxide layer and a high dielectric constant layer located on the substrate.

18. The method of claim 11, wherein forming the deep trench isolation structure comprises:
forming a seed layer on the substrate;
forming the epitaxial layer on the seed layer, and a depth of the epitaxial layer being greater than 4 microns;
etching the epitaxial layer to form one or more trenches;
etching the seed layer exposed in the trench to remove the seed layer;
performing a deposition process on a substrate surface area below the epitaxial layer to form the bottom insulating layer between the epitaxial layer and the substrate; and
filling an oxide layer in the trench, and the oxide layer forming the deep trench isolation structure in the epitaxial layer.

19. The method of claim 18, further comprising filling a high dielectric constant layer in the trench, the high dielectric constant layer being located between the oxide layer and the epitaxial layer.

20. The method of claim 11, wherein disposing the epitaxial layer on the bottom insulating layer comprises:
forming the epitaxial layer on a semiconductor substrate through a deposition process;
forming an insulating material on the epitaxial layer;
polishing the semiconductor substrate, and leaving only the insulating material on the epitaxial layer; and
disposing the epitaxial layer and the insulating material on the bottom insulating layer through bonding.
